(19) United States
(12) Patent Application Publication
(10) Pub. No.: US 2002/0081853 A1
(43) Pub. Date: Jun. 27, 2002

(54) Abrasive slurry and process for a chemical-mechanical polishing of a precious-metal surface

(76) Inventors: Gerhard Beitel, Kamakura-Shi (JP); Eugen Unger, Augsburg (DE); Annette Saenger, Dresden (DE)

Correspondence Address: LERNER AND GREENBERG, P.A., Post Office Box 2480, Hollywood, FL, 33022-2480, US

(21) Appl. No.: 10/023,136

(22) Filed: Dec. 17, 2001

Related U.S. Application Data
(63) Continuation of application No. PCT/DE00/01911, filed on Jun. 14, 2000.

(30) Foreign Application Priority Data
Jun. 15, 1999 (DE) 199 27 286.7

(51) Int. Cl. H01L 21/302; H01L 21/461

(52) U.S. Cl. 438/692

(57) ABSTRACT

An abrasive slurry for a chemical mechanical polishing of a precious-metal surface includes abrasive particles, which are in organic and/or aqueous suspension, an oxidizing agent and a complex-forming agent which shifts the equilibrium between the precious metal in elemental form and its ions in solution toward the formation of new ions. A chemical-mechanical polishing method is also provided.

### CROSS-REFERENCE TO RELATED APPLICATION

This application is a continuation of copending International Application No. PCT/DE00/01911, filed Jun. 14, 2000, which designated the United States.

### BACKGROUND OF THE INVENTION

Field of the Invention

The invention relates to an abrasive slurry and to a process for a chemical-mechanical polishing of a precious-metal surface, in which an improved abrasion rate is achieved.

In conventional DRAM (Dynamic Random Access Memory) components, silicon oxide/silicon nitride is used as the memory dielectric. The ever increasing storage density in DRAM components, as well as the development of what are known as nonvolatile memories (FRAM=Ferroelectric Random Access Memory) requires the use of new types of paraelectric or ferroelectric memory dielectrics. By way of example, barium strontium titanate (BST, (Ba,Sr)TiO₃) or lead zirconate (PZT, 25 Pb(Zr,Ti)O₃) or strontium bismuth tantalate (SBT, SrBi₂Ta₂O₉) are used.

Unfortunately, the use of the new paraelectrics and/or ferroelectrics also entails the use of new electrode and/or barrier materials. On account of their good resistance to oxidation and/or the formation of electrically conductive oxides, 4d and 5d transition metals, in particular platinum metals (Ru, Rh, Pd, Os, Ir, Pt) and their oxides are promising candidates for replacing doped silicon/polysilicon as electrode material and, for example, titanium nitride as barrier material. In particular, platinum itself is in widespread use as electrode material used in the development of innovative DRAM and FRAM (Ferroelectric Random Access Memory) components.

It has been found that these chemically highly inert electrode materials are very difficult to polish using conventional abrasive slurries which have become known hitherto for the chemical-mechanical polishing (CMP) of a precious-metal surface, which contain abrasive particles, such as for example Al₂O₃, SiO₂ and/or cerium oxide etc. and form a suspension with organic liquids, such as glycerol and/or polyalcohols or glycerol/polyalcohol/water mixtures. This is because the polishing operation is in this case achieved primarily in a mechanical manner, with the result that only a low abrasion rate is achieved. Abrasive slurries of this type are known, for example, from U.S. Pat. Nos. 5,527,423, 5,728,308, 5,244,534, and 5,783,489 and from Hoshino et al., “Chemical-Mechanical Polishing of Metalorganic Chemical-Vapor-Deposited Gold for LSI Interconnection”, Jpn. J. Appl. Phys. Vol. 32 (1993), pp. L392-L394 and from the text book by Steigerwald et al., “Chemical Mechanical Planarization of Microelectronic Materials”, Wiley 1997.

In general, in known abrasive processes for non-precious metal surfaces (for example tungsten), an oxidizing agent is also added to the slurry, in order to oxidize the metal surface and in this way to accelerate the polishing operation through the use of an additional chemical component. With the abovementioned new types of electrode material, the conventional slurries cannot be used in practice on account of their low abrasion rate, since the surface to be polished is chemically inert and the oxidizing agents added react only very slowly, if at all. Therefore, the abrasion takes place primarily in a mechanical manner. On account of the low abrasion rate, this may lead to very long process times until—by way of example—planarization of an electrode for a gigabit DRAM memory cell is completed using CMP. Furthermore, there is a risk of defects (scratches) forming on the surface to be polished.

### SUMMARY OF THE INVENTION

It is accordingly an object of the invention to provide an abrasive slurry and a process for the chemical-mechanical polishing of a precious-metal surface which overcome the above-mentioned disadvantages of the heretofore-known abrasive slurries and polishing processes of this general type and which have improved abrasion rates.

With the foregoing and other objects in view there is provided, in accordance with the invention, an abrasive slurry for a chemical-mechanical polishing of a precious-metal surface, including:

a suspension medium selected from the group consisting of an organic suspension medium and an aqueous suspension medium;

abrasive particles suspended in the suspension medium; and

an oxidizing agent and a complex-forming agent added to the suspension medium, the complex-forming agent shifting an equilibrium between a precious metal in elemental form and ions of the precious metal in solution toward a formation of the ions of the precious metal.

In other words, the invention relates to an abrasive slurry for the chemical-mechanical polishing of a precious-metal surface which, in addition to abrasive particles in organic and/or aqueous suspension, also contains an oxidizing agent and/or a complex-forming agent. The invention also relates to a process for the chemical-mechanical polishing of a precious-metal surface, in which the oxidation potential of the precious metal in the abrasive slurry is reduced by shifting the equilibrium between the precious metal in elemental form and in ionogenic (complexed) form.

According to an advantageous embodiment of the invention, the oxidizing agent used is at least one compound selected from the group consisting of oxygen, ozone, hydrogen peroxide and peroxodisulfate, hypochlorite, chlorate, perchlorate, bromate, iodate, permanganate, chromate, iron(III) compounds, such as for example Fe(A)₃ where A=F, Cl, Br, I, (NO₃) and/or Fe₂(SO₄)₃, K₃Fe(CN)₆; cerium(IV) compounds, such as for example Ce(SO₄)₂, Ce(NO₃)₄; nitrohydrochloric acid, chromosulfuric acid. Some oxidizing agents can also be used in combination as a mixture.

According to a further advantageous embodiment of the invention, the complex-forming agent used is ethylenediaminetetraacetic acid (EDTA), a crown ether, a nitrogen-containing macrocycle, such as for example a derivative of 1,4,8,11-tetraazacyclotetradecane, citric acid, chloride, bromide and/or cyanide (the latter three in the form of one of their salts). Phosphates, phosphonates and phosphinates can also be used as complex-forming agents for stable precious-metal complexes and are used so that the reaction equilibrium is shifted.

According to an advantageous embodiment, the abrasive slurry additionally contains surfactants which reduce the surface tension of the solution and therefore facilitates cleaning of the polished surfaces. The surfactants have no influence on the complexes formed, but can increase the wettability of the surfaces which are to be polished, so that complex-forming agents and oxidizing agents come into better contact with the metal surface or with metal particles which have been mechanically removed from the surface.

With the objects of the invention in view there is also provided, a chemical-mechanical polishing method, the method includes the steps of:

reducing an oxidation potential of a precious metal in an abrasive slurry by shifting an equilibrium between the precious metal in its elemental form and in its ionogenic and/or complexed form; and

polishing a surface of the precious metal with the abrasive slurry.

Other features which are considered as characteristic for the invention are set forth in the appended claims.

Although the invention is described herein as embodied in an abrasive slurry and a process for the chemical-mechanical polishing of a precious-metal surface, it is nevertheless not intended to be limited to the details described, since various modifications and changes may be made therein without departing from the spirit of the invention and within the scope and range of equivalents of the claims.

The construction and method of operation of the invention, however, together with additional objects and advantages thereof will be best understood from the following description of specific embodiments.

### DESCRIPTION OF THE PREFERRED EMBODIMENTS

In the abrasive slurry and the chemical-mechanical polishing method according to the invention, the equilibrium between the precious metal in elemental form and its ions in the solution is shifted in favor of the formation of new ions (e.g. Pt²⁺) by the use of suitable complex-forming agents. The oxidation potential of the precious metal in the solution is reduced by lowering the concentration of metal ions through complexing, as takes place, for example, when metallic gold is dissolved by cyanide liquor. When using a precious metal with a reduced oxidation potential, chemical-mechanical polishing is completed more quickly, since a reaction between the surface and abraded particles of the precious metal and the oxidizing agent employed takes place more quickly or becomes possible for the first time. Furthermore, it becomes possible to use weaker, less aggressive oxidizing agents. This in turn under certain circumstances has an advantageous effect on the service life of installations and operational safety measures.

Furthermore, the complex-forming agents keep the abraded precious metal in solution, so that re-deposition of the abraded metal or of metal compounds is prevented.

The choice of complex-forming agent is dependent on the nature of the surface which is to be polished. The complex-forming agent is intended to bond the metal atoms which are at the surface of the component to be polished and the abraded metal atoms quickly and permanently (as metal ions).

The literature provides considerable information about suitable complex-forming agents in acidic or basic medium for every precious metal and every precious-metal alloy which may occur as the material of the component to be polished. Multidentate ligands (such as for example EDTA) have proven suitable for using the chelate effect for keeping metal ions quickly and permanently in solution.

The complex formed and the free complex-forming agent are inert and are readily soluble in the abrasive slurry for the chemical-mechanical polishing of a precious-metal surface.

In the present context, the term “precious metal” is understood as meaning not only a pure precious metal (Ag, Au, Ru, Rh, Pd, Os, Ir, Pt), but also any metal and/or any alloy with a standard potential at the surface under standard conditions of greater than or equal to zero. Consideration is given in particular to platinum and iridium, for example for use as electrodes and/or barrier materials in gigabit DRAM memory cells and/or for the development of nonvolatile FRAM Ferroelectric Random Access Memory) components.

We claim:

1. An abrasive slurry for a chemical-mechanical polishing of a precious-metal surface, comprising:
a suspension medium selected from the group consisting of an organic suspension medium and an aqueous suspension medium;
abrasive particles suspended in said suspension medium; and
an oxidizing agent and a complex-forming agent added to said suspension medium, said complex-forming agent shifting an equilibrium between a precious metal in elemental form and ions of the precious metal in solution toward a formation of the ions of the precious metal.

2. The abrasive slurry according to claim 1, wherein said oxidizing agent includes at least one element selected from the group consisting of oxygen, ozone, hydrogen peroxide, peroxodisulfate, hypochlorite, chlorate, perchlorate, bromate, iodate, permanganate, chromate, an iron(III)-compound, nitrohydrochloric acid and chromosulfuric acid.

3. The abrasive slurry according to claim 1, wherein said complex-forming agent includes at least one element selected from the group consisting of ethylenediaminetetraacetic acid (EDTA), a crown ether, nitrogen-containing macrocycles, citric acid, chloride, bromide and cyanide.

4. The abrasive slurry according to claim 1, including a surfactant.

5. A chemical-mechanical polishing method, the method which comprises:
reducing an oxidation potential of a precious metal in an abrasive slurry by shifting an equilibrium between the precious metal in an elemental form and in at least one of an ionogenic form and a complexed form; and
polishing a surface of the precious metal with the abrasive slurry.
